(19) United States
(12) Patent Application Publication
(10) Pub. No.: US 2016/0233322 A1
(43) Pub. Date: Aug. 11, 2016

(54) METHOD FOR FABRICATING CHALCOGENIDE FILMS

(71) Applicant: G-FORCE NANOTECHNOLOGY LTD., Kaohsiung City (TW)

(72) Inventors: CHAO-HUI YEH, Hsinchiu (TW); JEN-KUAN CHIU, Hsinchiu (TW)

(21) Appl. No.: 14/985,010

(22) Filed: Dec. 30, 2015

Related U.S. Application Data
(60) Provisional application No. 62/112,717, filed on Feb. 6, 2015.

(51) Int. Cl. H01L 29/66; H01L 21/443; H01L 29/24; H01L 21/02; H01L 21/477

(52) U.S. Cl. CPC H01L 29/66969; H01L 29/6609; H01L 21/02565; H01L 21/02617; H01L 21/02664; H01L 21/477; H01L 29/24; H01L 21/443

(57) ABSTRACT

A method for fabricating a chalcogenide film is presented. The method includes providing a substrate in a chamber and performing a first atomic layer deposition process to form a first oxide film on the substrate; performing a first chalcogenization process including introducing a first chalcogen element to transform the first oxide film into a first chalcogenide film; and performing an annealing process on the first chalcogenide film.

### CROSS REFERENCE TO RELATED APPLICATIONS

This application claims the benefit of U.S. Provisional Application No. 62/112,717, filed Feb. 6, 2015, the entirety of which is incorporated by reference herein.

### BACKGROUND OF THE INVENTION

1. Field of the Invention

The invention relates to a method for fabricating chalcogenide films, and in particular it relates to a method for fabricating chalcogenide films using an atomic layer deposition process.

2. Description of the Related Art

Chalcogenide films have been studied and have been used in many applications in recent years. Chalcogenide films have a broad band gap and the potential to provide short wavelength optical emission. Typically, chalcogenide films include chalcogen atoms and at least one additional element that generally acts to change electrical characteristics.

A chalcogenide film may be fabricated from precursors by using a chemical vapor deposition (CVD) process or a metal organic chemical vapor deposition (MOCVD) process. Alternatively, a chalcogenide film may be peeled off from a layered chalcogenide bulk and then transferred to a substrate. However, challenges remain in providing a scalable chalcogenide film with a thinner and uniform thickness. Therefore, a new method for fabricating chalcogenide films is desirable.

### SUMMARY OF THE INVENTION

An embodiment of the invention provides a method for fabricating a chalcogenide film, wherein the method includes: providing a substrate in a chamber and performing a first atomic layer deposition process to form a first oxide film on the substrate; performing a first chalcogenization process comprising introducing a first chalcogen element to transform the first oxide film into a first chalcogenide film; and performing an annealing process on the first chalcogenide film.

An alternative embodiment of the invention provides a method for fabricating a chalcogenide film, wherein the method includes: providing a substrate in a chamber and performing a first atomic layer deposition process to form a first oxide film on the substrate; performing a second atomic layer deposition process to form a second oxide film on the first oxide film; performing a first chalcogenization process comprising introducing a first chalcogen element to transform the first oxide film and the second oxide film into a first chalcogenide film and a second chalcogenide film; and performing an annealing process on the first chalcogenide film and the second chalcogenide film.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1C illustrate cross-sectional views of intermediate steps in the process of fabricating a chalcogenide film according to an exemplary embodiment of the invention.

FIGS. 2A-2C illustrate cross-sectional views of intermediate steps in the process of fabricating a bilayer chalcogenide film according to alternative exemplary embodiment of the invention.

FIGS. 3A-3C illustrate cross-sectional views of intermediate steps in the process of fabricating a bilayer chalcogenide film according to another exemplary embodiment of the invention.

FIGS. 4A-4B are a Raman spectrum and an optical image for a monolayer WSe₂ chalcogenide film on a Al₂O₃ substrate, in accordance with some embodiments.

FIGS. 5A-5B are a Raman spectrum and an optical image for a bilayer WSe₂ chalcogenide film on a Al₂O₃ substrate, in accordance with some embodiments.

### DETAILED DESCRIPTION OF THE INVENTION

The purposes, features, and advantages of the embodiment of the invention can be better understood by referring to the following detailed description with reference to the accompanying drawings. The specification of the invention provides alternative embodiments to describe alternative features of performing the method of the invention. Furthermore, the configuration of each element in the embodiments is for the purposes of explanation, but is not intended to limit the present disclosure. In addition, the present disclosure may repeat reference numbers and/or letters in the various embodiments. This repetition is for the purpose of simplicity and clarity, and does not imply any relationship between the different embodiments and/or the configurations discussed.

The terms “about” and “substantially” typically mean +/−20% of the stated value, more typically +/−10% of the stated value and even more typically +/−5% of the stated value. The stated value of the present disclosure is an approximate value. When there is no specific description, the stated value includes the meaning of “about” or “substantially”.

An embodiment of the invention provides a method for fabricating a chalcogenide film with improved uniformity.

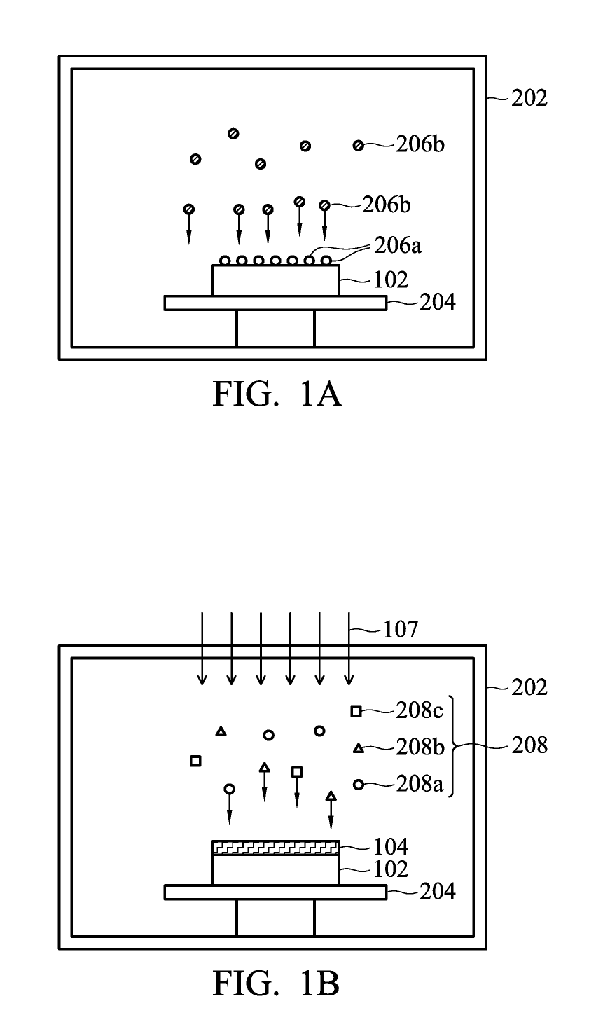

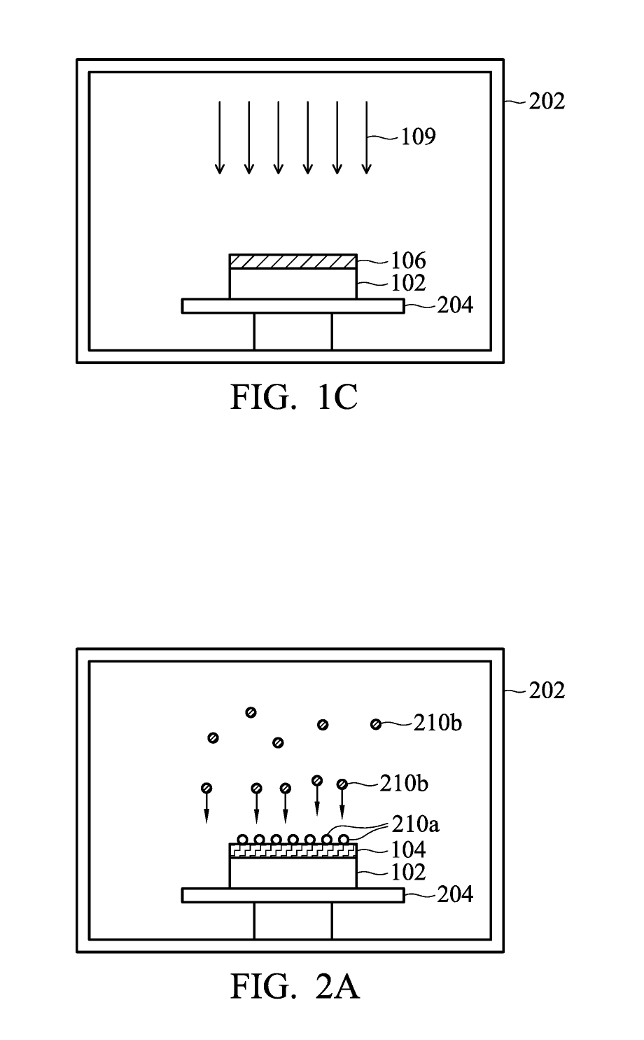

FIGS. 1A-1C illustrate cross-sectional views of intermediate steps in the process of fabricating a first chalcogenide film. Referring to FIG. 1A, a substrate 102 is provided on a holder 204 in a chamber 202 used for performing a first atomic layer deposition (ALD) process. A first ALD precursor is introduced into the chamber 202 to proceed with the first ALD process. In some embodiments, the first ALD precursor may include a first ALD element precursor 206a and an oxidizing gas 206b. The first ALD element precursor 206a may include transition metals, e.g. molybdenum (Mo), tungsten (W) or hafnium (Hf), or semiconductors, e.g. gallium (Ga), indium (In), germanium (Ge), tin (Sn), or zinc (Zn), or the like. The oxidizing gas 206b may include ozone (O₃) or oxygen gas (O₂). In some embodiments, as shown in FIG. 1A, the first ALD element precursor 206a adheres onto a surface of the substrate 102 and then reacts with the oxidizing gas 206b to form a first oxide film 104, as shown in FIG. 1B. In some embodiments, the substrate 102 may be a silicon substrate or a dielectric substrate, e.g. silicon oxide, silicon nitride, quartz, aluminum oxide, or glass. The first oxide film 104 may be a transition metal oxide film or a semiconductor oxide film, depending on the material of the first ALD element precursor 206a. The transition metal oxide film may include molybdenum oxide, tungsten oxide or hafnium oxide, and the semiconductor oxide film may include gallium oxide, indium oxide, germanium oxide, tin oxide, or zinc oxide. In some embodiments, the first ALD process for formation of the first oxide film 104 is performed at a temperature that is between about 150° C. and 600° C. In this embodiment, the thickness of the first oxide film 104 may be between about 1 nm and 10 nm, e.g. about 8 nm.

Subsequently, a first chalcogenization process is performed to transform the first oxide film 104 into a first chalcogenide film 106, as shown in FIG. 1C. During the first chalcogenization process, a first chalcogen precursor 208 is introduced into the chamber 202. The first chalcogen precursor 208 may include a first chalcogen element 208a, a hydrogen gas 208b, and a carrier gas 208c. In this embodiment, the first chalcogen element 208a may be sulfur (S), selenium (Se) or tellurium (Te). The carrier gas 208c may be nitrogen or argon. The first chalcogen element 208a replaces the oxygen atoms in the first oxide film 104, and the hydrogen gas 208b is used to assist the first chalcogenization process by reducing the first oxide film 104. In some embodiments, the first chalcogen element 208a is introduced at a flow rate that is between 2 and 100 sccm, the hydrogen gas 208b may be introduced at a flow rate that is between about 2 and 200 sccm, and the carrier gas 208c may be introduced at a flow rate that is between about 10 and 600 sccm. In some embodiments, the first chalcogenization process may be performed at a temperature that is between about 150° C. and 700° C.

In some embodiments, as shown in FIG. 1C, during the first chalcogenization process, an UV illumination process 107 may optionally be utilized to induce an UV-assisted photochemical reaction to facilitate the first chalcogenization process. The UV light having a wavelength between 160 nm and 400 nm may be utilized. Note that the UV illumination process 107 is an optional step and may be omitted. For example, in one embodiment, the first chalcogen element 208a comprises sulfur. In this case, the first chalcogen element 208a may react easily with the first oxide film 104, and the UV illuminating process 107 may be omitted.

After the first chalcogenization process, the first oxide film 104 is transformed into the first chalcogenide film 106 on the substrate, as shown in FIG. 1C. In some embodiments, the thickness of the first chalcogenide film 106 may be between about 1 nm and 10 nm, such as about 8 nm, depending closely on the thickness of the first oxide film 104. In this embodiment, the first chalcogenide film 106 may have at least one monolayer. In some embodiments, the first chalcogenide film 106 includes metal dichalcogenides, e.g. MoS₂, WS₂, HfS₂, MoSe₂, WSe₂, HfSe₂, MoTe₂, WTe₂ or HfTe₂, or II-VI, III-VI and IV-VI semiconductor chalcogenides, e.g. GaSe, In₂Se₃, GaTe, In₂Te₃, GeSe, GeTe, ZnSe, ZnTe, SnSe₂, SnTe₂, or the like.

Once the first chalcogenide film 106 has been formed, an annealing process 109 on the first chalcogenide film 106 may be utilized to remove defects adjacent to the interface between the first chalcogenide film 106 and the substrate 102 and improve the quality of the first chalcogenide film 106. In some embodiments, the annealing process 109 may be performed at a temperature that is between about 500° C. and 700° C., such as about 600° C., for about 10 minutes to 2 hours.

Since the first oxide film 104 is formed by the first ALD process, the first oxide film 104 and the subsequently formed first chalcogenide film 106 has a uniform and thinner thickness, and therefore, a uniform electrical performance. In addition, because the first ALD process and the first chalcogenization process are performed in the same chamber 202, the first chalcogenide film 106 is prevented from being contaminated by dust and other particles.

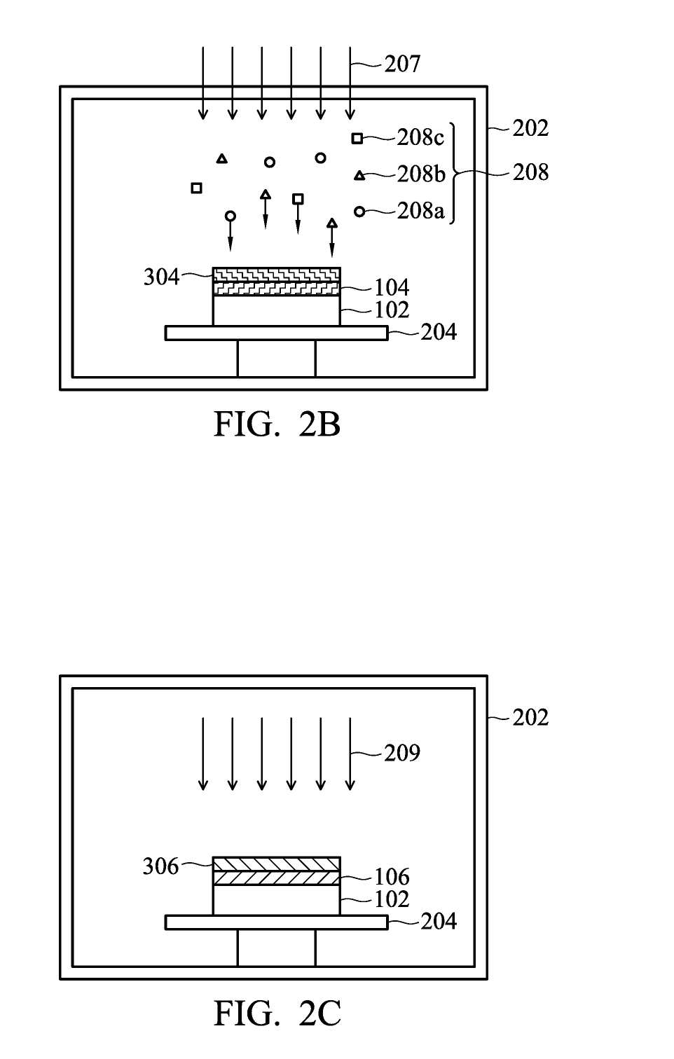

FIGS. 2A-2C illustrate cross-sectional views of intermediate steps in the process of fabricating a bilayer chalcogenide film according to an embodiment. In this embodiment, two or more oxide films are formed first and then simultaneously transformed into a bilayer chalcogenide film. Referring to FIG. 2A, once the first oxide film 104 has been formed as shown in FIG. 1B, a second ALD process is performed to form a second oxide film 304 on the first oxide film 104. The second oxide film 304 may be the same or different from the first oxide film 104. A second ALD precursor is introduced into the chamber 202 to proceed with the second ALD process. In some embodiments, the second ALD precursor may include a second ALD element precursor 210a and an oxidizing gas 210b. The second ALD element precursor may include transition metals, e.g. molybdenum (Mo), tungsten (W) or hafnium (Hf), or semiconductors, e.g. gallium (Ga), indium (In), germanium (Ge), tin (Sn), or zinc (Zn), or the like. The oxidizing gas 210b may include ozone (O₃) or oxygen gas (O₂). In some embodiments, as shown in FIG. 2A, the second ALD element precursor 210a adheres onto a top surface of the first oxide film 104 and then reacts with the oxidizing gas 210b to form a second oxide film 304, as shown in FIG. 2B. The second oxide film 304 may be a transition metal oxide film or a semiconductor oxide film, depending on the material of the second ALD element precursor 210a. The transition metal oxide film may include molybdenum oxide, tungsten oxide or hafnium oxide, and the semiconductor oxide film may include gallium oxide, indium oxide, germanium oxide, tin oxide, or zinc oxide. In some embodiments, the second ALD process for formation of the second oxide film 304 is performed at a temperature that is between about 150° C. and 600° C. In this embodiment, the second oxide film 304 may be between about 1 nm and 10 nm, e.g. about 8 nm.

Subsequently, the first chalcogenization process is performed to transform the first oxide film 104 and the second oxide film 304 into the first chalcogenide film 106 and a second chalcogenide film 306, respectively, as shown in FIG. 2C. During the first chalcogenization process, a first chalcogen precursor 208 may be introduced into the chamber 202. The first chalcogen precursor 208 may include a first chalcogen element 208a, a hydrogen gas 208b, and a carrier gas 208c. In this embodiment, the first chalcogen element 208a may be sulfur (S), selenium (Se), or tellurium (Te). The carrier gas 208c may be nitrogen or argon. The first chalcogen element 208a replaces the oxygen atoms in the first oxide film 104 and the second oxide film 304, and the hydrogen gas 208b is used to assist the first chalcogenization process by reducing the first oxide film 104 and the second oxide film 304. In some embodiments, the first chalcogen element 208a is introduced at a flow rate that is between 2 and 100 sccm, the hydrogen gas 208b may be introduced at a flow rate that is between about 2 and 200 sccm, and the carrier gas 208c may be introduced at a flow rate that is between about 10 and 600 sccm. In some embodiments, the first chalcogenization process may be performed at a temperature that is between about 150° C. and 700° C.

In some embodiments, as shown in FIG. 2C, during the first chalcogenization process, an UV illumination process 207 may optionally be utilized to induce an UV-assisted photochemical reaction to facilitate the first chalcogenization process. UV light having a wavelength between 160 nm and 400 nm may be utilized. Note that the UV illumination process 207 is an optional step and may be omitted. For example, in one embodiment, the first chalcogen element 208a comprises sulfur. In this case, the first chalcogen element 208a may react easily with the first oxide film 104, and the UV illuminating process 207 may be omitted.

After the first chalcogenization process, the first oxide film 104 is transformed into the first chalcogenide film 106 on the substrate, and the second oxide film 304 is transformed into the second chalcogenide film 306 on the first chalcogenide film 106, as shown in FIG. 2C. In some embodiments, the thickness of the first chalcogenide film 106 and the second chalcogenide film 306 independently may be between about 1 nm and 10 nm, such as about 8 nm, depending closely on the thickness of the first oxide film 104 and the second oxide film 304. In this embodiment, each of the first chalcogenide film 106 and the second chalcogenide film 306 may have at least one monolayer. In some embodiments, the first chalcogenide film 106 and the second chalcogenide film 306 may include metal dichalcogenides, e.g. MoS₂, WS₂, HfS₂, MoSe₂, WSe₂, HfSe₂, MoTe₂, WTe₂ or HfTe₂, or II-VI, III-VI and IV-VI semiconductor chalcogenides, e.g. GaSe, In₂Se₃, GaTe, In₂Te₃, GeSe, GeTe, ZnSe, ZnTe, SnSe₂, SnTe₂, or the like. In this embodiment, the first chalcogenide film 106 may be different from the second chalcogenide film 306 in cases where the first oxide film 104 is different from the second oxide film 304.

Once the first chalcogenide film 106 and the second chalcogenide film 306 have been formed, an annealing process 209 on the first chalcogenide film 106 and the second chalcogenide film 306 may be utilized to remove defects adjacent to the interface between the first chalcogenide film 106 and the substrate 102 and the interface between the first chalcogenide film 106 and the second chalcogenide film 306 to improve the quality of the first chalcogenide film 106 and second chalcogenide film 306. In some embodiments, the annealing process 209 may be performed at a temperature that is between about 500° C. and 700° C., such as about 600° C. for about 10 minutes to 2 hours.

Since the first oxide film 104 is formed by the first ALD process and the second oxide film 304 is formed by the second ALD process, the subsequently formed first chalcogenide film 106 and the second chalcogenide film 306 both have a uniform and thinner thickness and thus have a uniform electric performance. In addition, because the first ALD process, the second ALD process, and the first chalcogenization process are performed in the same chamber 202, the first chalcogenide film 106 and the second chalcogenide film 306 are prevented from being contaminated by dust and other particles. Moreover, bilayer chalcogenide films such as first/second chalcogenide films 106/306 may act as a diode with adjustable electrical characteristics and good performance.

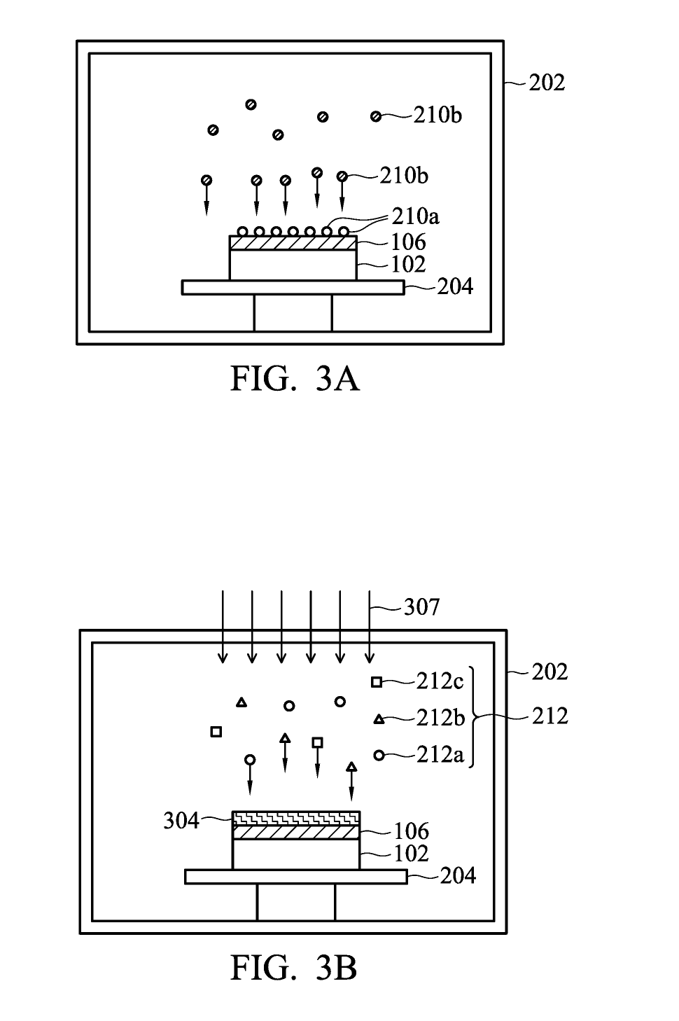

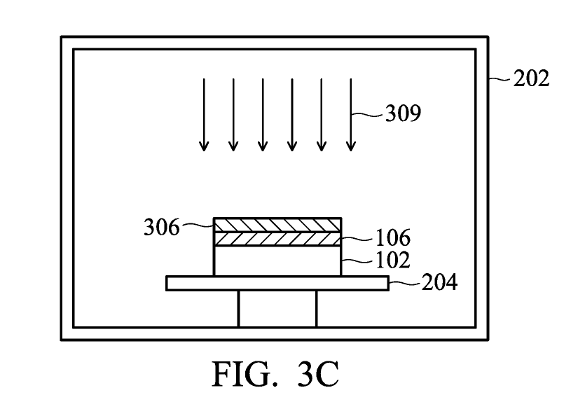

FIGS. 3A-3C illustrate cross-sectional view of intermediate steps in the process of fabricating a bilayer chalcogenide films according to an alternative embodiment. In this embodiment, two or more oxide films are transformed into chalcogenide films independently to form a bilayer chalcogenide film. Referring to FIG. 3A, once the first chalcogenide film 106 has been formed as shown in FIG. 1C, the second ALD process is performed to form a second oxide film 304 on the first chalcogenide film 106. In FIG. 3A, the second ALD precursor is introduced into the chamber 202 to proceed with the second ALD process. In some embodiments, the second ALD precursor includes a second ALD element precursor 210a and an oxidizing gas 210b. The second ALD element precursor 210a includes transition metals, e.g. Mo, W or Hf, or semiconductors, e.g. Ga, In, Ge, Sn or Zn, or the like. The oxidizing gas 210b includes ozone (O₃) or oxygen gas (O₂). In this embodiment, as shown in FIG. 3A, the second ALD element precursor 210a adheres onto a top surface of the first oxide film 104 and then reacts with the oxidizing gas 210b to form a second oxide film 304 on the first chalcogenide film 106, as shown in FIG. 3B. The second oxide film 304 may be a transition metal oxide film or a semiconductor oxide film, depending on the material of the second ALD element precursor 210a. The transition metal oxide film includes molybdenum oxide, tungsten oxide or hafnium oxide, and the semiconductor oxide film includes gallium oxide, indium oxide, germanium oxide, tin oxide, or zinc oxide. In some embodiments, the second oxide film 304 and the first oxide film 104 may be the same or different. In some embodiments, the second ALD process 303 for formation of the second oxide film 304 may be performed at a temperature that is between about 150° C. and 600° C. In this embodiment, the thickness of the first oxide film 104 and the thickness of the second oxide film 304 may each range from about 1 nm to 10 nm, e.g. about 8 nm.

Subsequently, the second chalcogenization process is performed to transform the second oxide film 304 into the second chalcogenide film 306, as shown in FIG. 3C. During the second chalcogenization process, a second chalcogen precursor 212 may be introduced into the chamber 202. The second chalcogen precursor 212 includes a second chalcogen element 212a, a hydrogen gas 212b, and a carrier gas 212c. In this embodiment, the second chalcogen element 212a may be S, Se, or Te. The carrier gas 212c may be nitrogen or argon. The second chalcogen element 212a replaces the oxygen atoms in the second oxide film 304, and the hydrogen gas 212b is used to assist the second chalcogenization process by reducing the second oxide film 304. In some embodiments, the second chalcogen element 212a may be introduced at a flow rate that is between 2 and 100 sccm, the hydrogen gas 212b may be introduced at a flow rate that is between about 2 and 200 sccm, and the carrier gas 212c may be introduced at a flow rate that is between about 10 and 600 sccm. In some embodiments, the second chalcogenization process may be performed at a temperature that is between about 150° C. and 700° C.

In some embodiments, as shown in FIG. 3B, during the second chalcogenization process, a UV illumination process 307 may optionally be utilized to induce an UV-assisted photochemical reaction to facilitate the second chalcogenization process. The UV light having a wavelength between 160 nm and 400 nm may be utilized. Note that the UV illumination process 307 is an optional step and may be omitted. For example, in one embodiment, the second chalcogen element 212a comprises sulfur. In this case, the first chalcogen element 208a may react easily with the first oxide film 104, and the UV illuminating process 307 may be omitted.

After the second chalcogenization process, the second oxide film 304 is transformed into the second chalcogenide film 306 on the first chalcogenide film 106, as shown in FIG. 3C. In some embodiments, the thickness of the second chalcogenide film 306 may be between about 1 nm and 10 nm, such as about 8 nm, depending on the thickness of the second oxide film 304. In this embodiment, the second chalcogenide film 306 may have at least one monolayer. In some embodiments, the second chalcogenide film 306 may include metal dichalcogenides, e.g. MoS₂, WS₂, HfS₂, MoSe₂, WSe₂, HfSe₂, MoTe₂, WTe₂ or HfTe₂, or II-VI, III-VI and IV-VI semiconductor chalcogenides, e.g. GaSe, In₂Se₃, GaTe, In₂Te₃, GeSe, GeTe, SnSe₂, SnTe₂, ZnSe, ZnTe, or the like. In this embodiment, the first chalcogenide film 106 may be different from the second chalcogenide film 306 in cases where the first oxide film 104 is different from the second oxide film 304.

Once the first chalcogenide film 106 has been formed, an annealing process 309 on the second chalcogenide film 306 may be utilized to remove defects adjacent to the interface between the first chalcogenide film 106 and the substrate 102 and the interface between the first chalcogenide film 106 and the second chalcogenide film 306 and improve the quality of the first chalcogenide film 106 and the second chalcogenide film 306. In some embodiments, the annealing process 309 may be performed at a temperature that is between about 500° C. and 700° C., such as about 600° C. for about 10 minutes to 2 hours.

Since the second oxide film is formed by the second ALD process, the subsequently formed second chalcogenide film 306 will have a uniform and thinner thickness, and therefore, a uniform electric performance. In addition, because the second ALD process and the second chalcogenization process are performed in the same chamber 202, the first chalcogenide film 106 and the second chalcogenide film 306 are prevented from being contaminated by dust and other particles. Moreover, bilayer chalcogenide films such as first/second chalcogenide films 106/306 may act as a diode with adjustable electrical characteristics and good performance.

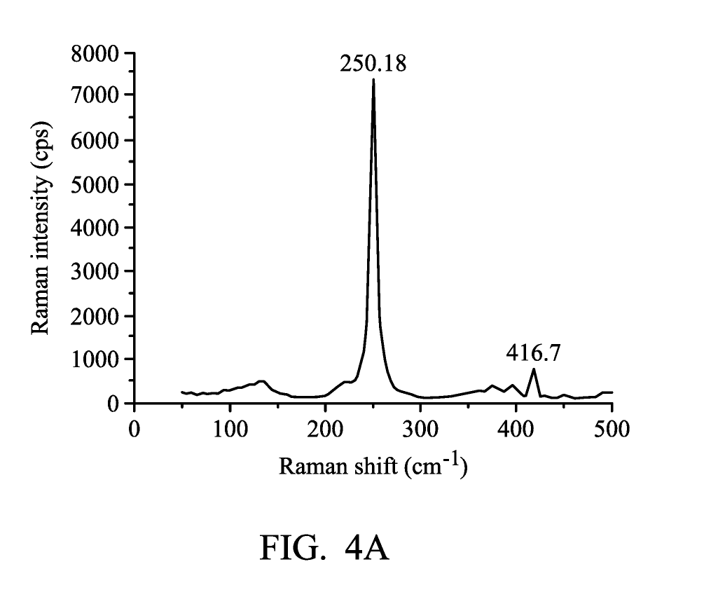

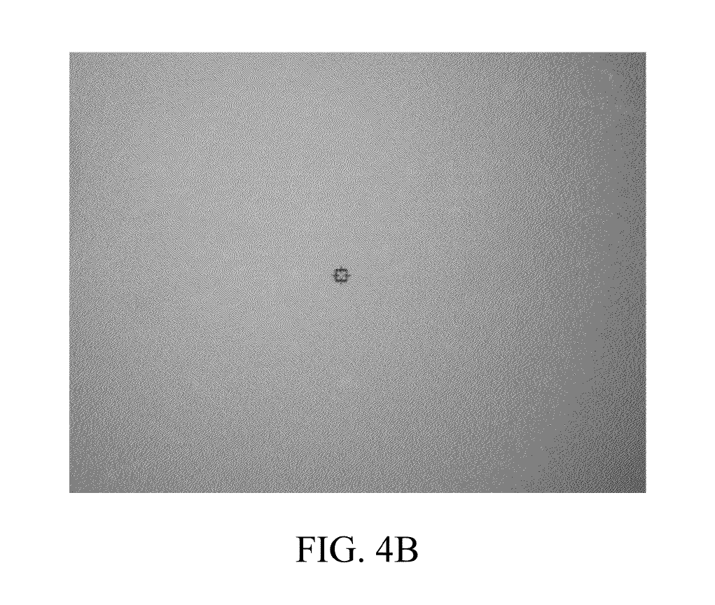

Referring to FIGS. 4A-4B, a Raman spectrum and an optical image for a monolayer WSe₂ chalcogenide film on a Al₂O₃ substrate in accordance with some embodiments are illustrated. In FIG. 4A, the Raman peaks at about 417 cm⁻¹ and at about 250 cm⁻¹ can be observed, which respectively correspond to the Al₂O₃ substrate and the monolayer WSe₂ chalcogenide film thereon. In FIG. 4B, no noticeable spot is observed on the surface of the monolayer WSe₂ chalcogenide film, which indicates the resulting film fabricated by the disclosure has a uniform surface.

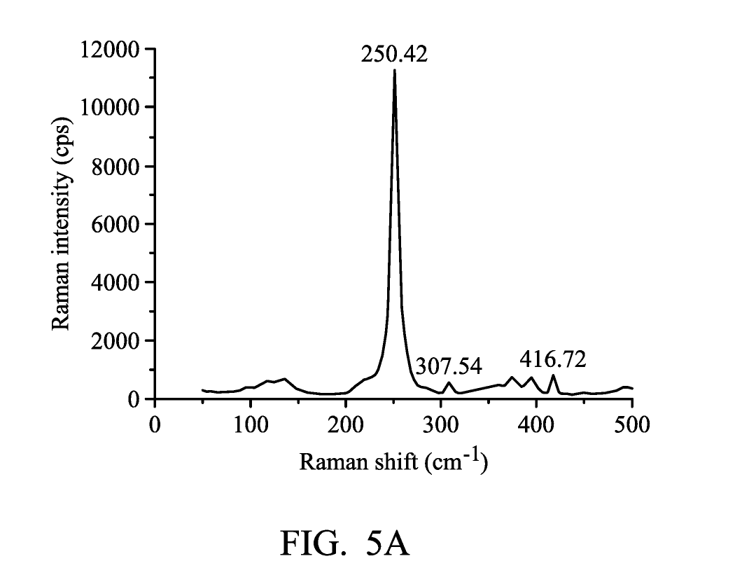

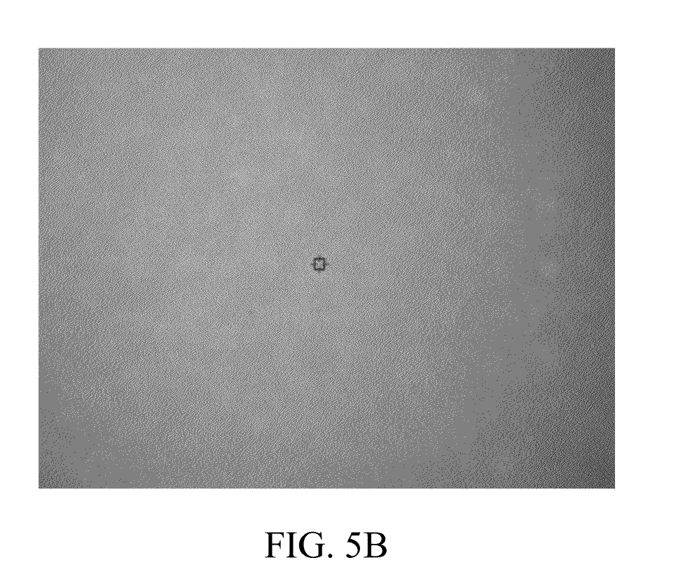

Now referring to FIG. 5A-5B, a Raman spectrum and an optical image for a bilayer WSe₂ cholcagenide film on a Al₂O₃ substrate in accordance with some embodiments are illustrated. In FIG. 5A, the Raman peaks at about 417 cm⁻¹ and at about 250 cm⁻¹ can be observed, which is at the same location as the Raman peaks shown in FIG. 4A. Note that a Raman peak at about 308 cm⁻¹ shown in FIG. 5A is the interlayer vibration of the bilayer WSe₂ chalcogenide film. Furthermore, referring to FIG. 5A, the Raman intensity of the Raman peak at about 250 cm⁻¹ that is higher than the Raman peak in FIG. 4A presents that the bilayer chalcogenide film has been formed. FIG. 5B shows the uniform surface of the bilayer WSe₂ chalcogenide film grown on a Al₂O₃ substrate in accordance with some embodiments illustrated.

Although the above-described chalcogenide film is a monolayer or bilayer chalcogenide film, the chalcogenide film may be a chalcogenide film with three or more sublayers. In some embodiments, the material of at least one sublayer of the multi-layer chalcogenide film may be different form the others to provide a heterostructure. In other embodiments, the materials of each sublayer of the multi-layer chalcogenide film may are different form each other.

Repeating the ALD growth of oxide film and chalcogenization process, multilayer of chalcogenide heterostructures with different combination of metal/semiconductor and chalcogen elements can be formed.

Although some embodiments of the present disclosure have been described in detail, it is to be understood that the invention is not limited to the disclosed embodiments. It will be apparent to those skilled in the art that various modifications and variations can be made to the disclosed embodiments. Therefore, it is intended that the specification and examples be considered as exemplary only, with the true scope of the disclosure being indicated by the following claims and their equivalents.

What is claimed is:

1. A method for fabricating a chalcogenide film, comprising:
providing a substrate in a chamber;
performing a first atomic layer deposition process to form a first oxide film on the substrate; and
performing a first chalcogenization process comprising introducing a first chalcogen element to transform the first oxide film into a first chalcogenide film.

2. The method as claimed in claim 1, further comprising:
after performing the first chalcogenization process, performing an annealing process on the first chalcogenide film.

3. The method as claimed in claim 2, further comprising:
before the annealing process, performing a second atomic layer deposition process to form a second oxide film on the first chalcogenide film; and
performing a second chalcogenization process comprising introducing a second chalcogen element to transform the second oxide film into a second chalcogenide film.

4. The method as claimed in claim 3, wherein each of the first oxide film and the second oxide film independently comprises a transition metal oxide film or a semiconductor oxide film.

5. The method as claimed in claim 4, wherein the transition metal oxide film comprises molybdenum oxide, tungsten oxide or hafnium oxide, and the semiconductor oxide film comprises gallium oxide, indium oxide, germanium oxide, tin oxide, or zinc oxide.

6. The method as claimed in claim 3, wherein each of the first chalcogen element and the second chalcogen element independently comprises sulfur, selenium or tellurium.

7. The method as claimed in claim 3, wherein each of the first chalcogenide film and the second chalcogenide film independently comprises at least one monolayer.

8. The method as claimed in claim 3, wherein the first oxide film is different from the second oxide film.

9. The method as claimed in claim 3, wherein each of the thickness of the first chalcogenide film and the thickness of the second chalcogenide film is between 1 nm and 10 nm.

10. The method as claimed in claim 1, wherein the substrate comprises silicon or a dielectric material, wherein the dielectric material comprises silicon oxide, silicon nitride, quartz, aluminum oxide, or glass.

11. The method as claimed in claim 1, wherein the first atomic layer deposition process is performed at a temperature between 150° C. and 600° C.

12. The method as claimed in claim 1, wherein the first chalcogenization process comprises using an UV-assisted photochemical reaction at a temperature between 150° C. and 700° C.

13. The method as claimed in claim 1, further comprising:
during the introduction of the first chalcogen element, introducing a hydrogen gas as a reducing gas and an argon gas as a carrier gas.

14. A method for fabricating a chalcogenide film, comprising:
providing a substrate in a chamber;
performing a first atomic layer deposition process to form a first oxide film on the substrate;
performing a second atomic layer deposition process to form a second oxide film on the first oxide film; and
performing a first chalcogenization process comprising introducing a first chalcogen element to transform the first oxide film and the second oxide film into a first chalcogenide film and a second chalcogenide film.

15. The method as claimed in claim 14, further comprising:
after performing the first chalcogenization process, performing an annealing process on the first chalcogenide film and the second chalcogenide film.

16. The method as claimed in claim 14, wherein each of the first oxide film and the second oxide film independently comprises a transition metal oxide film or a semiconductor oxide film.

17. The method as claimed in claim 16, wherein the transition metal oxide film comprises molybdenum oxide, tungsten oxide or hafnium oxide, and the semiconductor oxide film comprises gallium oxide, indium oxide, germanium oxide, tin oxide, or zinc oxide.

18. The method as claimed in claim 14, wherein each of the first chalcogen element and the second chalcogen element independently comprises sulfur, selenium or tellurium.

19. The method as claimed in claim 14, wherein each of the first chalcogenide film and the second chalcogenide film independently comprises at least one monolayer.

20. The method as claimed in claim 14, wherein the first oxide film is different from the second oxide film.

21. The method as claimed in claim 14, wherein each of the thickness of the first chalcogenide film and the thickness of the second chalcogenide film is between 1 nm and 10 nm.

22. The method as claimed in claim 14, wherein the substrate comprises silicon or a dielectric material, wherein the dielectric material comprises silicon oxide, silicon nitride, quartz, aluminum oxide, or glass.

23. The method as claimed in claim 14, wherein the first atomic layer deposition process is performed at temperature that is between 150° C. and 600° C.

24. The method as claimed in claim 14, wherein the first chalcogenization process comprises using an UV-assisted photochemical reaction at a temperature between 150° C. and 700° C.

25. The method as claimed in claim 14, further comprising:
during the introduction of the first chalcogen element, introducing a hydrogen gas as a reducing gas and an argon gas as a carrier gas.

26. A method for fabricating a chalcogenide film, comprising:
providing a substrate in a chamber;
performing a plurality of atomic layer deposition processes to form a plurality of oxide films on the substrate, wherein at least one of the plurality of oxide films is different from the others;
performing a first chalcogenization process comprising introducing a first chalcogen element to transform the plurality of oxide films into a plurality of chalcogenide films.

27. The method as claimed in claim 26, wherein each one of the plurality of oxide films is different from each other.
